(19) United States
(12) Patent Application Publication
(10) Pub. No.: US 2025/0066609 A1
(43) Pub. Date: Feb. 27, 2025

(54) RESIN COMPOSITION

(71) Applicant: NAN YA PLASTICS CORPORATION, TAIPEI (TW)

(72) Inventors: Te-Chao Liao, TAIPEI (TW); Chi-Lin Chen, TAIPEI (TW); Hung-Yi Chang, TAIPEI (TW)

(73) Assignee: NAN YA PLASTICS CORPORATION, TAIPEI (TW)

(21) Appl. No.: 18/467,736

(22) Filed: Sep. 15, 2023

(30) Foreign Application Priority Data
Aug. 23, 2023 (TW) 112131621

(51) Int. Cl. C08L 79/08; H05K 1/03

(52) U.S. Cl. CPC C08L 79/08; H05K 1/0373; C08L 2201/02; C08L 2203/20; C08L 2207/324

(57) ABSTRACT

The disclosure provides a resin composition, which includes 30 wt % to 60 wt % of a bismaleimide resin; 1 wt % to 10 wt % of a liquid rubber resin; and 20 wt % to 50 wt % of a filler, based on a total weight of the resin composition.

### CROSS-REFERENCE TO RELATED APPLICATION

This application claims the priority benefit of Taiwan application serial no. 112131621, filed on Aug. 23, 2023. The entirety of the above-mentioned patent application is hereby incorporated by reference herein and made a part of this specification.

### BACKGROUND

### Technical Field

The disclosure relates to a composition, and particularly relates to a resin composition.

### Description of Related Art

In recent years, due to the development of 5G communication and millimeter wave communication, mobile phones, base stations, servers, etc. have been applied to higher frequencies (6˜77 GHz), so higher frequency substrate materials have to be used to be suitable for 5G high frequencies. In addition, copper clad laminate materials also have to be developed toward the goal of low dielectric properties. In the current low dielectric formula, a certain ratio of liquid rubber may be added to reduce the dissipation factor to less than 0.0020, but the glass transition temperature is low. Therefore, how to develop materials having excellent electrical properties and in line with the characteristics of high-frequency printed circuit boards, such as materials having both the high glass transition temperature and the dissipation factor, is still one of the urgent problems in the technical field of printed circuit boards.

### SUMMARY

The disclosure provides a resin composition, including: based on the total weight of the resin composition, 30 wt % to 60 wt % of a bismaleimide resin; 1 wt % to 10 wt % of a liquid rubber resin; and 20 wt % to 50 wt % of a filler.

In an embodiment of the disclosure, the bismaleimide resin includes DCPD-BMI, KI-50P, KI-70, or a combination thereof.

In an embodiment of the disclosure, the liquid rubber resin includes LDM-03-07, LDM-02, 1,2-SBS, or a combination thereof.

In an embodiment of the disclosure, the resin composition further includes 0.1 wt % to 3 wt % of a coupling agent and 0.1 wt % to 2 wt % of a catalyst.

In an embodiment of the disclosure, the resin composition further includes 10 wt % to 20 wt % of a flame resisting agent.

The disclosure provides an electronic component, including a substrate formed by the resin composition.

In an embodiment of the disclosure, the glass transition temperature of the substrate is greater than or equal to 250° C.

In an embodiment of the disclosure, the substrate has a dissipation factor less than or equal to 0.002 at a frequency of approximately 10 GHz.

In an embodiment of the disclosure, the substrate has a dielectric constant less than or equal to 3.2 at a frequency of approximately 10 GHz.

In an embodiment of the disclosure, the substrate is a copper foil substrate.

Based on the above, when applied to copper foil substrates, the resin composition of the disclosure can achieve a high glass transition temperature (greater than or equal to 250° C.) and a low dissipation factor (less than or equal to 0.002). In addition, the resin composition of the disclosure has a non-polar backbone structure, so it is not easily polarized in an electric field, thereby significantly reducing the dielectric constant (less than or equal to 3.2).

### DESCRIPTION OF THE EMBODIMENTS

The following are examples of the contents of the disclosure described in detail. The implementation details provided in the embodiments are for illustration purposes, and are not intended to limit the scope of protection of the disclosure. Persons with ordinary knowledge in the art can modify or change these implementation details according to the needs of the actual implementation.

Ranges may be expressed herein as “approximately” one particular value to “approximately” another particular value, which can also be expressed directly as one particular value and/or to another particular value. When expressing the range, another embodiment includes the one particular value and/or to the other particular value. Similarly, when values are expressed as approximations, by use of the antecedent “approximately”, it is understood that the particular value forms another embodiment. It is further understood that an endpoint of each range is clearly related or unrelated to the other endpoint.

In this document, non-limiting terms (such as: may, can, for example, or other similar terms) are non-essential or optional implementation, inclusion, addition, or presence.

Unless otherwise defined, all terms (including technical and scientific terms) used herein have the same meaning as commonly understood by one of ordinary skill in the art to which this disclosure belongs. It will also be understood that the terms (such as those defined in commonly used dictionaries) should be interpreted to have meanings consistent with those in the relevant technical context and should not be interpreted in an idealized or overly formal sense, unless explicitly defined as such.

As used herein, the so-called “bivalent organic group” is an organic group having two bonding positions, and the “bivalent organic group” can form two chemical bonds via these two bonding positions.

The disclosure provides a resin composition, including: based on the total weight of the resin composition, 30 wt % to 60 wt % of a bismaleimide (BMI) resin; 1 wt % to 10 wt % of a liquid rubber resin; and 20 wt % to 50 wt % of a filler. The disclosure combines the bismaleimide resin with the liquid rubber resin and the filler, which can improve the heat resistance of high-frequency substrate materials and reduce the dissipation factor of high-frequency substrate materials.

In some embodiments, based on the total weight of the resin composition, the weight percentage of the bismaleimide resin is 30 wt % to 60 wt %, such as 35 wt %, 45 wt %, or 55 wt %.

In some embodiments, the bismaleimide resin has a structure represented by the following Formula (1):

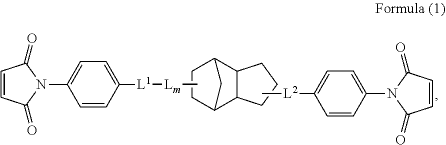

in which L represents a dicyclopentadienyl group, a divalent organic group derived from a phenolic compound, or a combination thereof, L¹ and L² each represent a divalent organic group derived from a phenolic compound, and m represents an integer from 0 to 18.

In some embodiments, the phenolic compounds include phenol. In some embodiments, the divalent organic group is preferably a divalent organic group including a maleimide group. In some embodiments, L is preferably a combination of a dicyclopentadienyl and a divalent organic group derived from a phenolic compound. In some embodiments, L represents

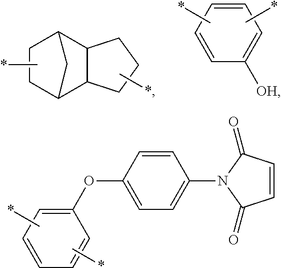

or a combination thereof, in which * represents a bonding position. In some embodiments, L¹ and L² each represent

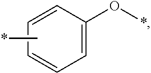

in which * represents the bonding position.

In some embodiments, the bismaleimide resin has a structure represented by the following Formula (2):

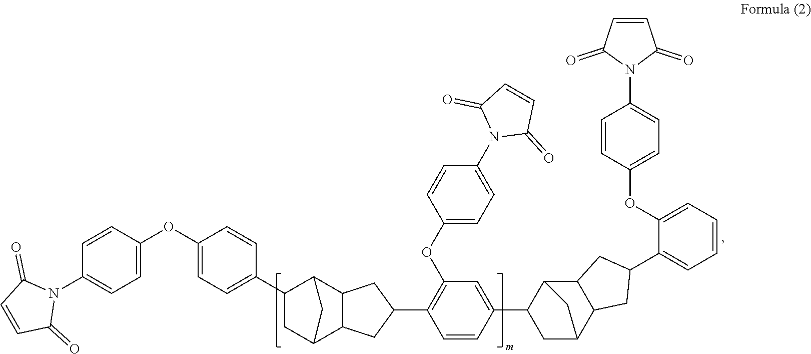

in which m represents an integer from 0 to 18, preferably from 2 to 10.

For example, a synthesis method of bismaleimide resin includes the following. First, 1 mol of dicyclopentadiene phenolic resin (trade name ERM6140, manufactured by Songyuan Co., Ltd., weight average molecular weight 1,300) and 1.25 mol of 4-halonitrobenzene (in which the halogen may be fluorine, chlorine, bromine, or iodine) is added into 6 moles of dimethylacetamide (DMAC) used as a reaction solvent and is reacted at a temperature of 120° C. for 300 minutes, so as to carry out the nitration reaction. Next, hydrogen gas is introduced to react at a temperature of 90° C. for 480 minutes to perform a hydrogenation reaction, so as to form a modified dicyclopentadiene-type diamine. Next, 3 moles of maleic anhydride and 9.7 wt % of toluenesulfonic acid are added to react at a temperature of 120° C. for 420 minutes to produce a second resin, which is a bismaleimide resin whose main chain includes a dicyclopentadiene structure (DCPD-BMI for short) and has a structure represented by Formula (2), and an average molecular weight may be of 800 to 10,000, preferably 1,000 to 4,000.

In some embodiments, based on the total weight of the resin composition, the weight percentage of the liquid rubber resin is 1 wt % to 10 wt %, such as 2 wt %, 5 wt %, or 8 wt %. In some embodiments, the liquid rubber resin includes LDM-03-07, LDM-02, 1,2-SBS, or a combination thereof.

In some embodiments, based on the total weight of the resin composition, the weight percentage of the filler is 20 wt % to 50 wt %, such as 30 wt %, 35 wt %, or 40 wt %. In some embodiments, the filler has a spherical shape, and the particle size (D50) of the filler is 0.3 μm to 3 μm. In some embodiments, the filler has a maximum particle size (D99) no greater than 10 μm. In some embodiments, the filler contains a surface modification such as acrylic or vinyl. In some embodiments, the filler is the SiO₂ filler provided by Third Age Technology.

In some embodiments, the resin composition further includes a coupling agent. In some embodiments, based on the total weight of the resin composition, the weight percentage of the coupling agent is 0.1 wt % to 3 wt %, such as 0.5 wt %, 1 wt %, or 1.5 wt %. Adding the coupling agent can enhance the compatibility and crosslinking degree of the resin composition to the glass fiber cloth and powder. In some embodiments, the content of the coupling agent in the resin composition is 0.1 part per hundred parts of resin (phr) to 3 phr of the coupling agent. In some embodiments, the content of the coupling agent in the resin composition is approximately 1 phr. In some embodiments, the coupling agent is a siloxane coupling agent. In some embodiments, the coupling agent is vinyl silane or acrylic silane. In some embodiments, the coupling agent is a coupling agent with the trade name of Z-6030 provided by DOW.

In some embodiments, the resin composition further includes a flame resisting agent. In some embodiments, based on the total weight of the resin composition, the weight percentage of the flame resisting agent is 10 wt % to 20 wt %, such as 12 wt %, 15 wt %, or 18 wt %. In some embodiments, the flame resisting agent is a phosphorus-based flame resisting agent. In some embodiments, the flame resisting agent is a flame resisting agent with the trade name of PX200 provided by Daihachi Chemical Industry Co., Ltd.

In some embodiments, the resin composition further includes a catalyst. In some embodiments, based on the total weight of the resin composition, the weight percentage of the catalyst is 0.1 wt % to 2 wt %, such as 0.5 wt %, 1 wt %, or 1.5 wt %. In some embodiments, the content of the catalyst in the resin composition is preferably 0.5 phr to 1.2 phr. In some embodiments, the catalyst is a catalyst with the trade name of DCP provided by ARKEMA.

The resin composition of the disclosure may be suitable for forming a substrate of an electronic component. In some embodiments, the substrate is a copper foil substrate. In some embodiments, the substrate has the following specifications: a glass transition temperature (Tg) greater than 250° C. (for example, approximately 250° C. to 260° C.); and a dissipation factor (Df) less than or equal to approximately 0.002. In some embodiments, a dielectric constant (Dk) of the substrate is less than or equal to approximately 3.2 (for example, approximately 3.0 to 3.15). In some embodiments, a peel strength of the substrate is greater than or equal to approximately 4.5 lb/in (for example, approximately 4.5 lb/in to 5.2 lb/in). In some embodiments, a heat resistance of the substrate has passed a test.

The implementation and effect of the disclosure will be described in detail below by using the copper foil substrates made of the resin compositions of the embodiments and comparative examples. However, the disclosure is not limited to the following embodiments and comparative examples.

According to composition ratios in Table 1 below, the resin composition is mixed with MEK to form a varnish of a thermosetting resin composition. The resulting varnish is impregnated with Nanya fiberglass cloth (NANYA Plastics Industry Co., Ltd., cloth model 1078LD) at room temperature, and then dried at approximately 130° C. (the temperature of the impregnator) for a few minutes to obtain a prepreg with a resin content of 60 wt %. Afterward, 4 pieces of prepreg are stacked between two pieces of copper foil with a thickness of approximately 35 μm, kept at a constant temperature at a pressure of 25 kg/cm² and a temperature of 85° C. for 20 minutes, heated to 210° C. at a heating rate of 3° C./min, kept at a constant temperature for 120 minutes, and then slowly cooled to 130° C. to produce a 0.5 mm thick copper foil substrate.

In Embodiment 1 to Embodiment 6, the “DCPD-BMI” used is a bismaleimide resin (DCPD-MI) having the structure represented by the Formula (2).

In Embodiment 2 to Embodiment 4, the “KI-50P” and “KI-70” used are respectively bismaleimide resins of trade names KI-50P and KI-70 series sold by K.I Chemical Industry Co., LTD.

In Embodiment 1, Embodiment 2, Embodiment 4, Embodiment 5, and Comparative Example 5, the “LDM-03-07” and “LDM-02” used are respectively liquid rubber resins of trade names LDM-03-07 and LDM-02 series sold by Dainippon Ink & Chemicals, Inc.

In Embodiment 3, Embodiment 6, Comparative Example 1, Comparative Example 3, and Comparative Example 5, the “1,2-SBS” used is a liquid rubber resin of the trade name 1,2-SBS series sold by NIPPON SODA.

In Comparative Example 1 to Comparative Example 6, the “RI 257” and the “RI 184” used are respectively liquid rubber resins with trade names RI 257 and RI 184 series sold by CRAY VALLEY.

In Embodiment 1 to Embodiment 6 and Comparative Example 1 to Comparative Example 6, the “PX200” used is a flame resisting agent with the trade name PX200 series sold by Daihachi Chemical Industry Co., Ltd.

In Embodiment 1 to Embodiment 6 and Comparative Example 1 to Comparative Example 6, the “DCP” used is a catalyst with the trade name DCP series sold by ARKEMA.

In Embodiment 1 to Embodiment 6 and Comparative Example 1 to Comparative Example 6, the “Z-6030” used is a siloxane coupling agent with the trade name Z-6030 series sold by DOW.

In Embodiment 1 to Embodiment 6 and Comparative Example 1 to Comparative Example 6, the SiO₂ used is a SiO₂ filler sold by Third Age Technology.

Items of the copper foil substrate such as the glass transition temperature, the dielectric constant, the dissipation factor, the peel strength, and the heat resistance are evaluated in the following manner, and the evaluation results are listed in Table 1.

### Glass Transition Temperature (Tg)

The glass transition temperature (Tg) of the resin composition in the copper foil substrate is measured by using a dynamic mechanical analyzer (DMA). When the Tg is high, it shows that the resin composition has a good ability to resist phase change, that is, a good heat resistance.

### Dielectric Constant (Dk)

The dielectric constant at a frequency of approximately 10 GHz is measured by using a dielectric analyzer (model E4991A, manufactured by Agilent Technologies, Inc.) When the dielectric constant is small, it shows that the resin composition in the copper foil substrate has good dielectric properties.

### Dissipation Factor (Df)

The dissipation factor at a frequency of approximately 10 GHz is measured by using a dielectric analyzer (model E4991A, manufactured by Agilent Technologies, Inc.) When the dissipation factor is small, it shows that the resin composition in the copper foil substrate has good dielectric properties.

### Peel Strength

The peel strength between the prepreg and the copper foil is tested according to IPC-TM-650-2.4.8 test method.

### Heat Resistance

Heat the copper foil substrate sample in a stress pot with a temperature of 120° C. and a stress of 2 atm for 120 minutes and then immerse in a soldering furnace of 288° C. and record the time required for the board to blister. If the board blistering time exceeds 10 minutes, it is indicated as “OK”, and if the board blistering time is shorter than 10 minutes, it is indicated as “NG”.

TABLE 1

| | | Embodiment | | | | | | Comparative example | | | | | |
|---|---|---|---|---|---|---|---|---|---|---|---|---|---|
| Ingredient/Evaluation items | | 1 | 2 | 3 | 4 | 5 | 6 | 1 | 2 | 3 | 4 | 5 | 6 |
| Bismaleimide | DCPD-BMI | 20 | 20 | 20 | 20 | 20 | 20 | 20 | 45 | 5 | 20 | | 25 |
| resin | KI-50P | | | | 10 | 10 | 10 | | | | | 10 | 20 |
| (wt %) | KI-70 | 20 | 20 | 20 | 10 | 10 | 10 | 5 | 20 | 20 | | 10 | 20 |
| Liquid rubber | LDM-03-07 | 6 | | | 6 | | | | | | | 10 | |
| (wt %) | LDM-02 | | 6 | | | 6 | | | | | | | |
| | 1,2-SBS | | | 6 | | | 6 | 15 | | 10 | | 10 | |
| | RI 257 | | | | | | | 6 | 6 | 11 | | | |
| | RI 184 | | | | | | | | | | 6 | 6 | 6 |
| Flame | PX200 | 14 | 14 | 14 | 14 | 14 | 14 | 14 | 14 | 14 | 24 | 14 | 9 |
| resisting agent | | | | | | | | | | | | | |
| (wt %) | | | | | | | | | | | | | |
| Catalyst | DCP | 1 | 1 | 1 | 1 | 1 | 1 | 2.5 | 3 | 3.5 | 1 | 1 | 1 |
| (phr) | | | | | | | | | | | | | |
| Siloxane | Z-6030 | 1 | 1 | 1 | 1 | 1 | 1 | 1 | 2 | 1 | 1 | 6 | 1 |
| coupling agent | | | | | | | | | | | | | |
| (phr) | | | | | | | | | | | | | |
| Filler | SiO₂ | 40 | 40 | 40 | 40 | 40 | 40 | 40 | 15 | 40 | 50 | 40 | 20 |
| (wt %) | | | | | | | | | | | | | |

| | | | | | | | | | | | | |
|---|---|---|---|---|---|---|---|---|---|---|---|---|
| Tg | 250 | 255 | 260 | 258 | 257 | 257 | 155 | 242 | 165 | 165 | 145 | 240 |
| Dk (10 GHz) | 3.1 | 3.0 | 3.05 | 3.15 | 3.1 | 3.03 | 3.1 | 4.2 | 3.3 | 3.5 | 3.3 | 4.3 |
| Df × 10³ (10 GHz) | 1.6 | 1.7 | 1.5 | 1.6 | 1.9 | 1.8 | 2.0 | 5.4 | 2.3 | 1.7 | 1.6 | 4.7 |
| Peel strength (lb/in) | 4.5 | 4.7 | 5.0 | 4.9 | 5.2 | 5.1 | 2.1 | 4.7 | 2.2 | 1.5 | 2.5 | 4.3 |
| Heat resistance | OK | OK | OK | OK | OK | OK | NG | OK | NG | NG | NG | OK |

### Evaluation Results

From Embodiment 1 to Embodiment 6 of [Table 1], it may be seen that, from the copper foil substrates prepared by the resin composition having the composition ratios of the disclosure, the measured Tg is higher than 250° C., the dissipation factor Df is less than 0.002, and the dielectric constant Dk is less than 3.2. Moreover, the copper foil substrates of Embodiment 1 to Embodiment 6 also exhibit good peel strength (≥4.5 lb/in) and good heat resistance.

However, from Comparative Example 1 to Comparative Example 6 of [Table 1], it may be seen that, when the weight percentage of the bismaleimide resin is less than 30 wt % or greater than 60 wt %, the measured Tg values are all lower than 250° C. In addition, from Comparative Example 1, Comparative Example 3, and Comparative Example 5, it may be seen that, when the weight percentages of the liquid rubber resin are all greater than 10 wt %, the measured Tg is even lower than 165° C., and the performances of the peel strength and the heat resistance are not good.

In summary, the resin composition of the disclosure uses the bismaleimide resin as the main structure with the liquid rubber resin, apart from providing the high glass transition temperature and the low dissipation factor, a non-polar backbone structure is also provided. Therefore, it is not easily polarized in an electric field, thereby significantly reducing the dielectric constant. In addition, the resin composition of the disclosure can be directly or indirectly applied to copper foil substrates, and can be further processed to become other livelihood, industrial, or suitable electronic components or electronic products (such as: circuit boards or copper foil substrates). In addition, when applied to copper foil substrates, the resin composition of the disclosure is beneficial to the reduction of the dissipation factor, the improvement of the peel strength, and/or the improvement of the heat resistance.

What is claimed is:

1. A resin composition, comprising:
based on a total weight of the resin composition,
30 wt % to 60 wt % of a bismaleimide resin;
1 wt % to 10 wt % of a liquid rubber resin; and
20 wt % to 50 wt % of a filler.

2. The resin composition as claimed in claim 1, wherein the bismaleimide resin comprises DCPD-BMI, KI-50P, KI-70, or a combination thereof.

3. The resin composition as claimed in claim 1, wherein the liquid rubber resin comprises LDM-03-07, LDM-02, 1,2-SBS, or a combination thereof.

4. The resin composition as claimed in claim 1, further comprising 0.1 wt % to 3 wt % of a coupling agent and 0.1 wt % to 2 wt % of a catalyst.

5. The resin composition as claimed in claim 4, further comprising 10 wt % to 20 wt % of a flame resisting agent.

6. An electronic component, comprising:
a substrate formed by the resin composition according to claim 1.

7. The electronic component as claimed in claim 6, wherein a glass transition temperature of the substrate is greater than or equal to 250° C.

8. The electronic component as claimed in claim 6, wherein the substrate has a dissipation factor less than or equal to 0.002 at a frequency of approximately 10 GHz.

9. The electronic component as claimed in claim 6, wherein the substrate has a dielectric constant less than or equal to 3.2 at a frequency of approximately 10 GHz.

10. The electronic component as claimed in claim 6, wherein the substrate is a copper foil substrate.
